(19) United States
(12) Patent Application Publication
(10) Pub. No.: US 2006/0214173 A1
(43) Pub. Date: Sep. 28, 2006

(54) Light emitting diodes and methods of fabrication

(75) Inventors: Karl W. Beeson, Princeton, NJ (US); Scott M. Zimmerman, Baskin Ridge, NJ (US)

Correspondence Address: William Propp, Esq.;Goldeneye, Inc., Suite 233, 9747 Businesspark Avenue, San Diego, CA, 92131, US

(73) Assignee: Goldeneye, Inc.

(21) Appl. No.: 11/388,945

(22) Filed: Mar. 24, 2006

Related U.S. Application Data
(60) Provisional application No. 60/665,898, filed on Mar. 28, 2005.

(51) Int. Cl. H01L 33/00

(52) U.S. Cl. 257/88

(57) ABSTRACT

A light emitting diode includes a first doped semiconductor layer, an active region and a second doped semiconductor layer. The sectional area of the active region is less than the sectional area of the first doped semiconductor layer. One electrode of the light emitting diode is connected to the edge surfaces of the first doped semiconductor layer. The second electrode is connected to the second doped semiconductor layer. A method is described for fabricating the light emitting diode.

This application claims the benefit under 35 USC § 119(e) of U.S. Provisional Application No. 60/665,898, filed Mar. 28, 2005, the contents of which is hereby incorporated by reference in its entirety.

### FIELD OF THE INVENTION

The present invention relates to light emitting diodes and to methods for fabricating light emitting diodes.

### BACKGROUND OF THE INVENTION

Light emitting diodes can be fabricated by depositing one or more layers of a semiconductor material onto a growth substrate. Deposition methods can include chemical vapor deposition (CVD), metal-organic chemical vapor deposition (MOCVD), molecular beam epitaxy MBE), liquid phase epitaxy (LPE) and vapor phase epitaxy (VPE). When a layer of semiconductor material is deposited onto a growth substrate, tensile or compressive stresses can occur that affect the planarity of the deposited film and the growth substrate as well as the electrical and optical properties of the semiconductor layer.

In one example, gallium nitride based light emitting diode (LED) devices can be formed by depositing one or more thin layers of the semiconductors gallium nitride (GaN), aluminum gallium nitride (AlGaN), indium gallium nitride (InGaN) or aluminum indium gallium nitride (AlInGaN) onto non-native growth substrates such as sapphire or silicon carbide (SiC). Due to thermal expansion effects at high deposition temperatures and lattice mismatches between the semiconducting layer and the growth substrate, a significant number of defects are introduced into the semiconducting layers during deposition. For this reason many groups are pursuing freestanding GaN wafers as growth substrates. These efforts are still very expensive and limited by the size of the freestanding wafer. Alternatively, hydride vapor phase epitaxy (HVPE) has allowed for the creation of moderately thick (10 to 20 microns) layers of GaN on sapphire with reasonably high crystal quality. The stresses in such layers, however, lead to strains such as wafer bowing that make subsequent processing difficult, especially if traditional planar lithography or wafer-bonding steps are required.

It is well known that etching process steps subsequent to film deposition can modify the semiconductor layers formed on a growth substrate. Laser processing, for example, has been used to etch grooves in GaN layers deposited on sapphire as well as other transparent growth substrates. Pulsed lasers such as frequency-tripled or frequency-quadrupled yttrium aluminum garnet (YAG) lasers and excimer lasers can be utilized. Sufficient energy from the laser beam is present to dice GaN layers into individual LED dies via a localized ablation process.

Researchers at the University of California at Berkeley have also developed a process called laser liftoff whereby the entire GaN layer or array of GaN LED dies can be removed from an optically transparent growth substrate such as sapphire. For example, a sapphire wafer can be coated with the appropriate GaN semiconductor layers for LED fabrication, including the deposition of at least one of the metal contacts. Individual dies are scribed in the semiconducting layers using a narrow beam laser or by mechanical means. At this stage, the LED dies are still fully attached to the growth substrate. A transfer substrate is attached to the exposed surface of the array of dies opposite the growth substrate. Light from an excimer laser is directed through the bare face of the growth substrate to the semiconductor layer of the LED dies located on the opposite face of the growth substrate. Due to the difference in the absorption coefficients between the sapphire and the GaN at the excimer laser wavelength, the majority of the energy from the laser is preferentially deposited into the interface between the sapphire and the GaN LED dies. This effectively separates the GaN LED dies as a group from the sapphire growth substrate.

Subsequent to laser liftoff, additional metal contacts can be added to the exposed planar surfaces and the dies can be separated from the transfer substrate as individual devices. LED dies produced by the laser liftoff process suffer, however, from significant current spreading issues due to lack of an attached electrically conductive substrate and the thinness of the semiconductor layers. A typical total thickness of the semiconductor layers is approximately 4 microns. Various means of enhancing current spreading have been used for laser liftoff dies including metal grip contacts, transparent conductive coatings and wafer bonding of electrically-conducting, low-absorbing layers such as doped SiC.

In another device fabrication method, epitaxial lateral overgrowth can be used to form isolated single crystal regions within a GaN semiconductor layer. In this approach, epitaxial growth is preferentially biased in the lateral direction across a wafer to form narrow wings of high crystal quality material. However, a very close spacing on the order of 10 microns or so is required between isolated regions. The lateral growth process can make high-quality, small devices a few microns wide but large area devices are difficult to fabricate. The epitaxial lateral overgrowth process is appropriate for fabricating GaN diode lasers but has not proved useful for fabricated large area GaN LEDs.

In order to reduce current spreading issues in light emitting diodes and to produce devices that are on the order of one square millimeter or larger in area, there exists a need for LEDs with at least one thick semiconductor layer. In order to increase the light extraction efficiency of such a device, there also exists a need to position one of the two electrodes for such the device on the edge surfaces of the thick semiconductor layer rather than on the planar top or bottom surfaces of the layer.

In addition, there exists a need for a fabrication process whereby thicker, high-quality semiconductor layers and devices can be economically fabricated. Presently, more traditional patterning approaches are used, including the use of mask based lithography and etching processes. Unfortunately, nitride based devices in particular are difficult to etch, especially anisotropically. Etch rates on the order of hundreds of nm/minute limit the feature thicknesses that can be economically rendered in these materials. As such, the use of mechanical means such as dicing and laser scribing are typically used even in thin devices. Conversely, there is a desire to increase the thickness of at least one layer as stated earlier for current spreading considerations. Therefore, there exists a need for an improved high-speed method for patterning light emitting diodes. Such a fabrication process should also be able to operate on wafers that are bowed as well as on planar wafers.

Finally, there is a need for an improved interconnect means. Presently most LEDs are connected via a top wirebond or a flipchip design. In the case of wirebonds, light generated under the bond pad is usually lost or significantly reduced due to simple blockage. In addition, the typical material of choice is gold, which can lead to absorption of reflected rays even if the rays do escape from the die itself. Lastly, wirebonds necessitate the use of some form of strain relief, especially in high current devices. This limits optical design flexibility by typically requiring the use of a large polymer lens. Flip chip designs, conversely, eliminate the top wirebond issues but create issues related to reduced emission area and less than optimum current spreading. There exists the need for an alternate interconnect scheme that minimizes loss of active area while not requiring any top contact. Such a solution should allow for the use of thicker device layers and be compatible with laser liftoff approaches.

### SUMMARY OF THE INVENTION

One embodiment of this invention is at least one light emitting diode that is comprised of a first doped semiconductor layer, an active region underlying the first doped semiconductor layer and a second doped semiconductor layer underlying the active region. The first doped semiconductor layer has a first surface, a second surface opposite and substantially parallel to the first surface and an edge surface that connects the first surface and the second surface. In addition, the first doped semiconductor layer is a current spreading layer and has a first area in a plane substantially parallel to the second surface. The active region emits light and has a second area substantially parallel to second surface, where the second area is less than the first area. The first electrode is in contact with the edge surfaces of the first doped semiconductor layer and the second electrode underlies and is in contact with the second doped semiconductor layer.

In another embodiment of this invention, the first doped semiconductor layer is an n-doped semiconductor layer and the second doped layer is a p-doped layer. The n-doped layer can be formed by hydride vapor phase epitaxy.

In other embodiments of this invention, the light emitting diode device is a plurality of light emitting diodes. The plurality of light emitting diodes can be a linear array of light emitting diodes or a two-dimensional array of light emitting diodes.

In another embodiment of this invention, a two-dimensional array of light emitting diodes is comprised of columns of light emitting diodes and rows of light emitting diodes. Within the two-dimensional array of light emitting diodes, the first electrodes in a column of light emitting diodes are connected together and the second electrodes in a row of light emitting diodes are connected together. Applying a current to a first electrode of a column and a second electrode of a row causes the light emitting diode located at the intersection of the column and the row to emit light.

Another embodiment of this invention is a method for fabricating at least one light emitting diode. The method comprises: providing a growth substrate, depositing a first doped semiconductor layer onto one surface of the growth substrate, depositing an active region on the first doped semiconductor layer, and depositing a second doped semiconductor layer on the active region. A first array of parallel trenches is etched through the first doped semiconductor layer, the active region, and the second doped semiconductor layer. A second array of parallel trenches is etched through the first doped semiconductor layer, the active region, and the second doped semiconductor layer, whereby the second array of parallel trenches is substantially perpendicular to the first array of parallel trenches. The first and second arrays of parallel trenches form isolated semiconductor dies. A metal layer is deposited on the exposed surfaces of the dies and the growth substrate. Along the edges of the dies, a laser etching process removes the metal layer, the second doped semiconductor layer, and the active layer from each die. The resulting structures are LED dies, each die having two separate electrodes. One of the electrodes is on the edge surface of the first doped semiconductor layer.

These embodiments are enabled by the use of thicker layers available from HVPE type growths. In this case, there exists sufficient thickness within the device such that adequate contact area can be formed on the edges or sides of the die. In addition, the thicker layers enable the use of laser ablation techniques. Typically tolerances on the order of a micron or less are needed in such processes. This is difficult to control if the device layers are only a few microns thick. However if the devices are 10 or 20 microns thick, realistic depth tolerance can be realized. Lastly, any rapid removal process such as laser ablation creates some level of stress locally. The thicker layers are sufficiently robust to prevent cracking and chipping when a portion of the thickness is removed.

### BRIEF DESCRIPTION OF THE DRAWINGS

A more detailed understanding of the present invention, as well as other objects and advantages thereof not enumerated herein, will become apparent upon consideration of the following detailed description and accompanying drawings, wherein:

FIGS. 1A-1D illustrate a light emitting diode of this invention. FIG. 1A illustrates a top plan view of a light emitting diode. FIG. 11B is a cross-sectional view along the I-I plane of the light emitting diode illustrated in FIG. 1A. FIG. 1C is another cross-sectional view of the light emitting diode along the I-I plane. FIG. 1D is another cross-sectional view along the I-I plane of the light emitting diode illustrated in FIG. 1A and illustrates example emitted light rays.

FIG. 2 is a cross-sectional view of another embodiment of this invention that includes light extraction elements.

FIG. 3 is a cross-sectional view of another embodiment of this invention that includes additional reflecting elements.

FIG. 4 is a cross-sectional view of another embodiment of this invention that includes a wavelength conversion layer.

FIG. 5A-5B illustrate another embodiment of this invention that is a linear array of three light emitting diodes. FIG. 5A is a bottom plan view of the linear array. FIG. 5B is a cross-sectional view of the linear array along the I-I plane indicated in FIG. 5A.

FIG. 6A-6B illustrate another embodiment of this invention that is a two-dimensional array of nine light emitting diodes. FIG. 6A is a bottom plan view of the two-dimensional array. FIG. 6B is a cross-sectional view of the two-dimensional array along the I-I plane indicated in FIG. 6A.

FIG. 7A-7B illustrate another embodiment of this invention that is a two-dimensional array of nine light emitting diodes. FIG. 7A is a bottom plan view of the two-dimensional array. FIG. 7B is a cross-sectional view of the two-dimensional array along the I-I plane indicated in FIG. 7A.

FIG. 8 illustrates a cross-sectional view of a growth substrate of an embodiment of the present invention.

FIG. 9 illustrates a cross-section view of an assembly shown in FIG. 8 that includes a first doped semiconductor layer.

FIG. 10 illustrates a cross-section view of an assembly shown in FIG. 9 that further includes an active region.

FIG. 11 illustrates a cross-section view of an assembly shown in FIG. 10 that further includes a second doped semiconductor layer.

FIGS. 12A-12B illustrate an embodiment of this invention. FIG. 12A is a top plan view of an assembly shown in FIG. 11 of this invention indicating where etching will take place for a first array of trenches. FIG. 12B is a cross-sectional view in the I-I plane of the assembly illustrated in FIG. 12A.

FIG. 13A-133B illustrate an embodiment of this invention that includes a first array of trenches. FIG. 13A is a top plan view of an assembly shown in FIG. 12 that has a first array of etched trenches. FIG. 13B is a cross-sectional view in the I-I plane of the assembly illustrated in FIG. 13A.

FIG. 14A-14B illustrate an embodiment of this invention. FIG. 14A is a top plan view of an assembly of this invention shown in FIG. 13 indicating where etching will take place for a second array of trenches. FIG. 14B is a cross-sectional view in the II-II plane of the assembly illustrated in FIG. 14A.

FIG. 15A- 15B illustrate an embodiment of this invention. FIG. 15A is a top plan view of an assembly shown in FIG. 14 of this invention illustrating first and second arrays of etched trenches. FIG. 15B is a cross-sectional view in the II-II plane of the assembly illustrated in FIG. 15A.

FIG. 16A-16B illustrate an embodiment of this invention. FIG. 16A is a top plan view of an assembly shown in FIG. 15 of this invention that is coated with a metal layer. FIG. 16B is a cross-sectional view in the I-I plane of the assembly illustrated in FIG. 16A.

FIGS. 17A-17B illustrate an embodiment of this invention. FIG. 17A is a top plan view of an assembly shown in FIG. 16 of this invention indicating where etching will take place. FIG. 17B is a cross-sectional view in the I-I plane of the assembly illustrated in FIG. 17A.

FIGS. 18A-18B illustrate an embodiment of this invention. FIG. 18A is a top plan view of an assembly shown in FIG. 17 of this invention after etching has taken place. FIG. 18B is a cross-sectional view in the I-I plane of the assembly illustrated in FIG. 18A.

FIGS. 19A-19D illustrate cross-sectional views of another embodiment of this invention. FIG. 19A again illustrates the cross-sectional view of the assembly shown in FIG. 18B. FIG. 19B illustrates the attachment of a transfer substrate. FIG. 19C illustrates the use of laser light to detach the growth substrate via a liftoff process. FIG. 19D shows the assembly after the growth substrate is removed.

FIGS. 20A-20B again illustrates the assembly shown in FIGS. 18A-18B. FIG. 20A is a top plan view. FIG. 20B is a cross-sectional view along the I-I plan illustrated in FIG. 20A. Dashed lines show the edges of areas where the metal layer will be removed.

FIGS. 21A-21B illustrate an assembly having parallel strips where the metal layer has been removed by a laser etching process. FIG. 21A is a top plan view of the assembly. FIG. 21B is a cross-sectional view along the I-I plane illustrated in FIG. 21A.

FIGS. 22A-22B again illustrates the assembly shown in FIGS. 21A-21B. FIG. 22A is a top plan view. FIG. 22B is a cross-sectional view along the II-II plan illustrated in FIG. 22A. Dashed lines show the edges of areas where the metal layer will be removed.

FIGS. 23A-23B illustrate an assembly having perpendicular strips where the metal layer has been removed by a laser etching process. FIG. 23A is a top plan view of the assembly. FIG. 23B is a cross-sectional view along the I-I plane illustrated in FIG. 23A.

### DETAILED DESCRIPTION OF THE PREFERRED EMBODIMENTS

The preferred embodiments of the present invention will be better understood by those skilled in the art by reference to the above figures. The preferred embodiments of this invention illustrated in the figures are not intended to be exhaustive or to limit the invention to the precise form disclosed. The figures are chosen to describe or to best explain the principles of the invention and its applicable and practical use to thereby enable others skilled in the art to best utilize the invention.

The figures are not drawn to scale. In particular, the thickness dimension is expanded relative to the length and width dimensions in order to clearly illustrate the multiple layers of the devices.

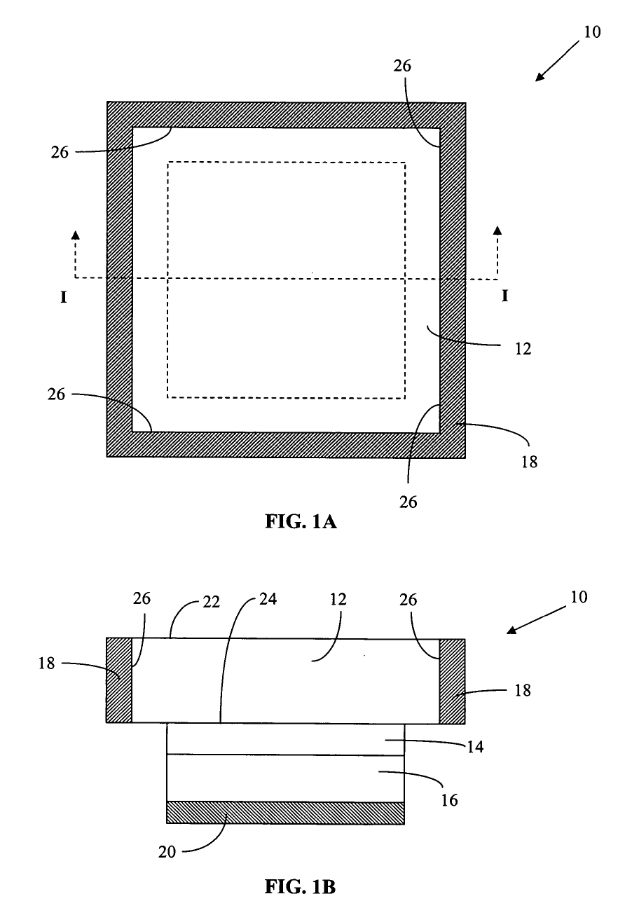

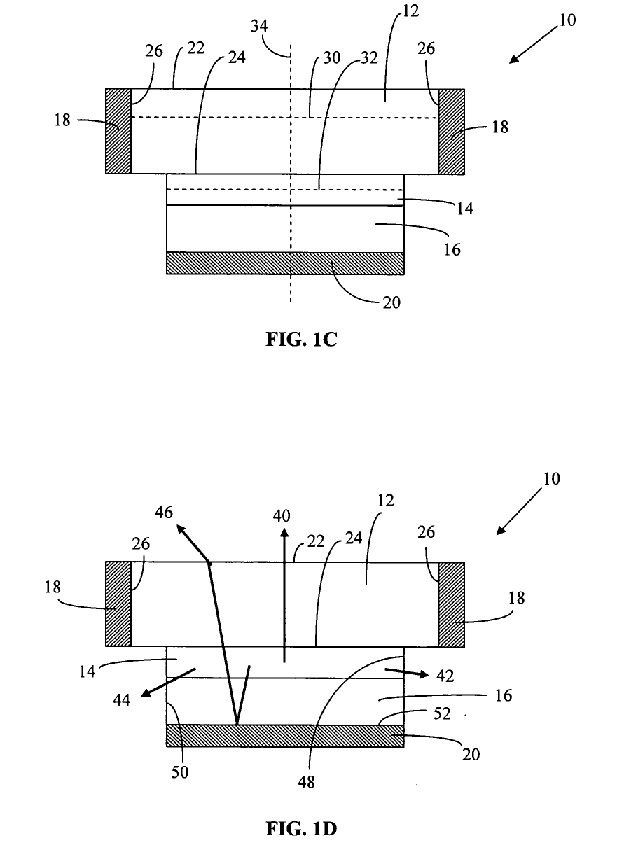

FIGS. 1A-1D illustrate one embodiment of this invention. FIG. 1A is a plan view of light emitting diode 10 of this invention and FIGS. 1B-1D are cross-sectional views of light emitting diode 10 along the I-I plane illustrated in FIG. 1A. Light emitting diode 10 is comprised of a first doped semiconductor layer 12, an active region 14 underlying the first doped semiconductor layer 12, a second doped semiconductor layer 16 underlying the active region 14, a first electrode 18 in contact with the edge surfaces 26 of the first semiconductor layer and a second electrode 20 underlying the second doped semiconductor layer. Applying an electric current through the device from the first electrode 18 to the second electrode 20 causes the active region 14 to emit light.

The first doped semiconductor layer 12 has a first surface 22, a second surface 24 opposite and substantially parallel to the first surface 22 and edge surfaces 26 that connect the first surface 22 and the second surface 24. The edge surfaces 26 are generally smaller in area and shorter in width than the first surface 22 and the second surface 24. The edge surfaces 26 may be perpendicular to the first surface 22 and the second surface 24 or the edge surfaces 26 may be angled with respect to the first surface and the second surface. The first doped semiconductor layer 12 is a current spreading layer and has a first sectional area 30 in a plane substantially parallel to the first surface 22 and the second surface 24 as shown in FIG. 1C. In order to increase the current spreading capability of the first doped semiconductor layer 12, preferably the first doped semiconductor layer is greater than 2 microns thick in the direction perpendicular to plane 30. More preferably, the thickness of the first doped semiconductor layer is greater than 5 microns thick. Most preferably, the thickness of the first doped semiconductor layer is greater than 10 microns thick.

The first surface 22 and the second surface 24 of the first doped semiconductor layer are substantially parallel. However, when the first doped semiconductor layer 12 is relatively thick, e.g. 5-10 microns or greater, the first doped semiconductor layer and the other layers fabricated on the first doped semiconductor layer may be slightly bowed. The bowing results from the fabrication process for making relatively thick semiconductor layers.

The active region 14 emits light when a current is applied to LED 10 through electrodes 18 and 20. The active region has a second sectional area 32 substantially parallel to the first surface 22 and the second surface 24, where the second sectional area 32 (shown in FIG. 1C) is less than the first sectional area 30. The active region 14 can be, for example, a p-n homoj unction, a p-n heteroj unction, a p-n double heterojunction, a single quantum well or a multiple quantum well, but is not limited to these specific types ofjunctions.

Light emitting diode 10 may have an axis of symmetry 34 as shown in FIG. 1C, but an axis of symmetry is not required.

The first doped semiconductor layer 12 can be an n-doped semiconductor layer and the second doped semiconductor layer 16 can be a p-doped semiconductor layer. Alternatively, the first doped semiconductor layer 12 can be a p-doped semiconductor layer and the second doped semiconductor layer 16 can be an n-doped semiconductor layer.

The first doped semiconductor layer 12, the active region 14 and the second doped semiconductor layer 16 can be fabricated from a wide variety of semiconductor materials from element groups III-V, II-VI and IV. Such semiconductor materials include the III-V materials used to fabricate LEDs and diode lasers. Example III-V materials include, but are not limited to, gallium nitride (GaN), aluminum nitride (AlN), aluminum gallium nitride (AlGaN), indium nitride (InN), indium gallium nitride (InGaN), aluminum indium gallium nitride (AlInGaN), aluminum gallium indium phosphide (AlGaInP), indium gallium phosphide (InGaP), gallium arsenide (GaAs), indium gallium arsenide (InGaAs) and indium gallium arsenide phosphide (InGaAsP). Example II-VI semiconductor materials include, but are not limited to, zinc oxide (ZnO), zinc sulfide (ZnS), cadmium sulfide (CdS), cadmium selenide (CdSe), cadmium telluride (CdTe) and mercury cadmium telluride (HgCdTe). Example group IV semiconductor materials include silicon (Si) and germanium (Ge).

If LED 10 is a GaN-based device, preferably the first doped semiconductor layer 12 is an n-doped GaN layer and the second doped semiconductor layer 16 is a p-doped GaN layer.

The first electrode 18 is in contact with the edge surfaces 26 of the first doped semiconductor layer 12. The second electrode 20 underlies and is in contact with the second doped semiconductor layer 16. The location of the first electrode 18 on the edge surfaces 26 of the first doped semiconductor layer 16 is a unique aspect of this invention. LEDs of the prior art position the first electrode either on the first surface 22 of the first doped semiconductor material or on the second surface 24 of the first doped semiconductor material. Positioning the first electrode on the edges 26 of the first doped semiconductor layer allows for a greater light emitting area from the first surface 22.

The first electrode 18 and the second electrode 20 can be fabricated from a wide variety of materials. Preferably the electrode materials have a high reflectivity so that light rays directed to the electrode materials will be reflected by the electrode materials. The electrodes may be formed from one or more metals or metal alloys containing, but not limited to, silver, aluminum, nickel, gold, titanium, chromium, platinum, palladium, rhodium, rhenium, ruthenium and tungsten. The electrodes may also be formed from transparent conductive oxides such as indium tin oxide (ITO).

A common electrode material for the top layer of the first electrode in prior art devices is gold. Gold has very good electrical properties, but is a poor optical reflector for visible light. It is advantageous to replace gold with a more reflective material. Preferably the first electrode 18 has a reflectivity greater than 60 percent. More preferably, the first electrode has a reflectivity greater than 80 percent.

The second electrode 20 usually covers a larger portion of the surface of LED 10 than the first electrode. Consequently, the reflectivity of the second electrode is more critical to the output efficiency of LED 10 than the reflectivity of the first electrode. Preferably the reflectivity of the second electrode 20 is greater than 92 percent. More preferably the reflectivity of the second electrode is greater than 96 percent. Most preferably the reflectivity of the second electrode is greater than 98 percent.

FIG. 1D illustrates example light rays 40, 42, 44 and 46 emitted by the active region 14. Example light ray 40 is emitted by active region 14, passes through the second surface 24, through the first doped semiconductor layer 12 and exits LED 10 through the first surface 22.

Example light ray 42 is emitted by the active region 14 and exits LED 10 through side surface 48. Example light ray 44 is emitted by the active region 14, is directed into the second doped semiconductor layer 16 and exits LED 10 through side surface 50.

Example light ray 46 is emitted by the active region 14, is directed through the second doped semiconductor layer 16 to surface 52 of the second electrode 20. Light ray 46 is reflected by the second electrode 20, passes through the second doped semiconductor layer a second time, passes through the active region, passes through the first semiconductor layer and exits LED 10 through the first surface 22.

Another embodiment of the present invention is LED 60 illustrated in cross-section in FIG. 2. LED 60 is similar to LED 10 except that the first surface 22 of the first doped semiconductor layer 12 includes light extracting elements 62. Light extracting elements 62 can be any surface features that improve the light extracting efficiency of LED 60. Light extracting elements 62 can be, for example, pyramids, cones, convex lenses, concave lenses, holes, ridges or grooves, but are not limited to these shapes. The light extracting elements may be fabricated from the material of the first semiconductor layer 12 as shown in FIG. 2 or the light extracting elements may be fabricated from a different material. Especially effective light extracting elements are pyramids and hemispherical lenses etched into the first semiconductor layer. The etching process may be any semiconductor dry or wet etching process including, but not limited to, laser etching, reactive ion etching, plasma etching, wet chemical etching and photoelectrochemical etching.

Example light ray 64 illustrates a possible path of a light ray emitted by the active region 14 of LED 60. Example light ray 64 is emitted by active region 14, is directed through the second surface 24, passes through the first semiconductor layer 12 and exits LED 60 through light extraction elements 62 in the first surface 22.

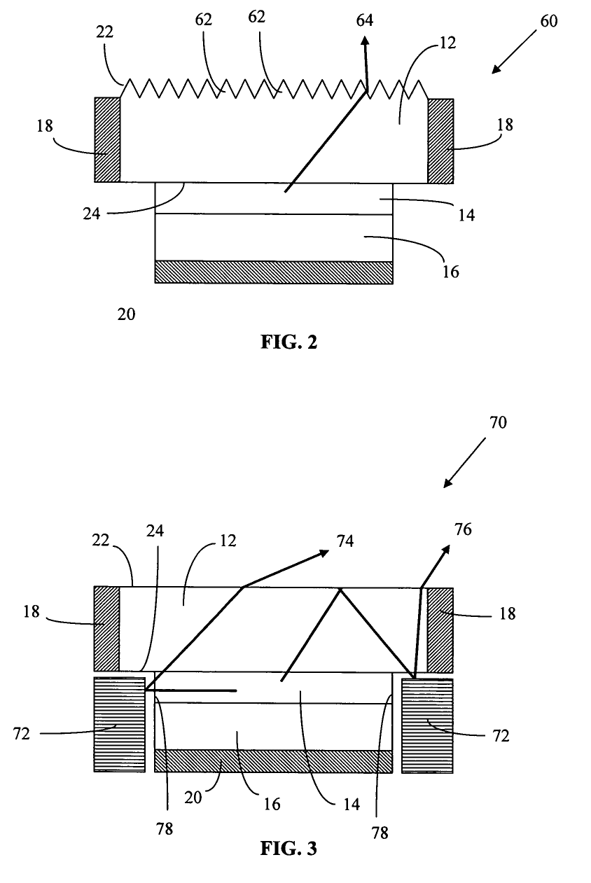

Another embodiment of the present invention is LED 70 illustrated in cross-section in FIG. 3. LED 70 is similar to LED 10 except that LED 70 includes reflectors 72. Reflectors 72 are located adjacent to the first semiconductor layer 12 and the first electrodes 18 and adjacent to edge surfaces 78 of the active region 14 and second semiconductor layer 16. Reflectors 72 reflect light that exits the second surface 24 of the first semiconductor layer and the edge surfaces 78 of the active region and the second semiconductor layer. The reflected light is directed back into the first semiconductor layer, the active region or the second semiconductor layer.

Example light rays 74 and 76 illustrate the utility of reflectors 72. The active region 14 emits example light ray 74. Example light ray 74 passes through edge surface 78, is reflected by reflector 72 and passes through edge surface 78 a second time into the active region 14. Example light ray 74 passes through the active region, passes through the second surface 24, passes through the first semiconductor layer 12 and exits LED 70 through the first surface 22.

Active region 14 emits example light ray 76. Example light ray 76 passes through the second surface 24 a first time, passes through the first semiconductor layer a first time and undergoes total internal reflection at the first surface 22. Example light ray 76 passes through the first semiconductor layer a second time, passes through the second surface 24 a second time and is reflected by reflector 72. Example light ray 76 passes through the second surface 24 a third time, passes through the first semiconductor layer a third time and exits LED 70 through the first surface 22.

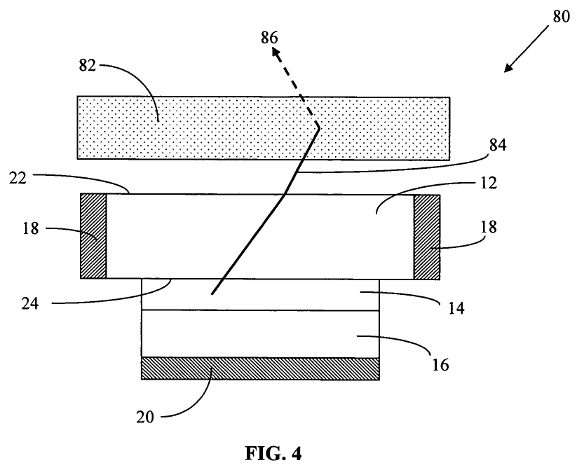

FIG. 4 is a cross-sectional view of another embodiment of this invention. LED 80 is similar to LED 10 except that LED 80 includes a wavelength conversion layer 82. Wavelength conversion layer converts light of a first wavelength range emitted by the active region 14 into light of a second wavelength range, where the second wavelength range is different than the first wavelength range.

The wavelength conversion layer 82 includes one or more wavelength conversion materials that facilitate the wavelength conversion. Exemplary wavelength conversion materials can include phosphor materials, quantum dot materials or a plurality of such materials. The wavelength conversion layer may further comprise a transparent host material into which the phosphor materials or the quantum dot materials are dispersed.

Phosphor materials are typically optical inorganic materials doped with ions of lanthanide (rare earth) elements or, alternatively, ions such as chromium, titanium, vanadium, cobalt or neodymium. The lanthanide elements are lanthanum, cerium, praseodymium, neodymium, promethium, samarium, europium, gadolinium, terbium, dysprosium, holmium, erbium, thulium, ytterbium and lutetium. Optical inorganic materials include, but are not limited to, sapphire (Al₂O₃), gallium arsenide (GaAs), beryllium aluminum oxide (BeAl₂O₄), magnesium fluoride (MgF₂), indium phosphide (InP), gallium phosphide (GaP), yttrium aluminum garnet (YAG or Y₃Al₅O₁₂), terbium-containing garnet, yttrium-aluminum-lanthanide oxide compounds, yttrium-aluminum-lanthanide-gallium oxide compounds, yttrium oxide (Y₂O₃), calcium or strontium or barium halophosphates (Ca,Sr,Ba)₅(PO₄)₃(Cl,F), the compound CeMgAl₁₁O₁₉, lanthanum phosphate (LaPO₄), lanthanide pentaborate materials ((lanthanide)(Mg,Zn)B₅O₁₀), the compound BaMgAl₁₀O₁₇, the compound SrGa₂S₄, the compounds (Sr,Mg,Ca,Ba)(Ga,Al,In)₂S₄, the compound SrS, the compound ZnS and nitridosilicate. There are several exemplary phosphors that can be excited at 250 nm or thereabouts. An exemplary red emitting phosphor is Y₂O₃:Eu³⁺. An exemplary yellow emitting phosphor is YAG:Ce³⁺. Exemplary green emitting phosphors include CeMgAl₁₁O₁₉:Tb³⁺, ((lanthanide)PO₄:Ce³⁺,Tb³⁺) and GdMgB₅O₁₀: Ce³⁺, Tb³⁺. Exemplary blue emitting phosphors are BaMgAl₁₀O₁₇:Eu²⁺ and (Sr,Ba,Ca)₅(PO₄)₃Cl:Eu²⁺. For longer wavelength LED excitation in the 400-450 nm wavelength region or thereabouts, exemplary optical inorganic materials include yttrium aluminum garnet (YAG or Y₃Al₅O₁₂), (Y₁₋ₐGdₐ)₃(Al_{1-b}Ga_{b})₅O₁₂, terbium-containing garnet, yttrium oxide (Y₂O₃), YVO₄, SrGa₂S₄, (Sr,Mg,Ca,Ba)(Ga,Al,In)₂S₄, SrS, and nitridosilicate. Exemplary phosphors for LED excitation in the 400-450 nm wavelength region include YAG:Ce³⁺, (Y₁₋ₐGdₐ)₃(Al_{1-b}Ga_{b})₅O₁₂:Ce³⁺, YAG:Ho³⁺, YAG:Pr³⁺, SrGa₂S₄:Eu²⁺, SrGa₂S₄;Ce³⁺, SrS:Eu²⁺ and nitridosilicates doped with Eu²⁺.

Quantum dot materials are small particles of inorganic semiconductors having particle sizes less than about 30 nanometers. Exemplary quantum dot materials include, but are not limited to, small particles of CdS, CdSe, ZnSe, InAs, GaAs and GaN. Quantum dot materials can absorb light at one wavelength and then re-emit the light at different wavelengths that depend on the particle size, the particle surface properties, and the inorganic semiconductor material.

The transparent host materials include polymer materials and inorganic materials. The polymer materials include, but are not limited to, acrylates, polystyrene, polycarbonate, fluoroacrylates, perfluoroacrylates, fluorophosphinate polymers, fluorinated polyimides, polytetrafluoroethylene, fluorosilicones, sol-gels, epoxies, thermoplastics, thermosetting plastics and silicones. Fluorinated polymers are especially useful at ultraviolet wavelengths less than 400 nanometers and infrared wavelengths greater than 700 nanometers owing to their low light absorption in those wavelength ranges. Exemplary inorganic materials include, but are not limited to, silicon dioxide, optical glasses and chalcogenide glasses.

A single type of phosphor material or quantum dot material may be incorporated in the wavelength conversion layer or a mixture of phosphor materials and quantum dot materials may be incorporated into the wavelength conversion layer. Utilizing a mixture of more than one such material is advantageous if a broad spectral emission range is desired.

Example light rays 84 and 86 in FIG. 4 illustrate the fuiction of the wavelength conversion layer 82. The active region 14 emits example light ray 84 of a first wavelength range. Example light ray 84 of a first wavelength range passes through the second surface 24, passes through the first semiconductor layer 12 and passes through the first surface 22. Example light ray 84 of a first wavelength range enters the wavelength conversion layer 82 and is converted to light ray 86 of a second wavelength range. Light ray 86 of a second wavelength range exits the wavelength conversion layer 82 and LED 80.

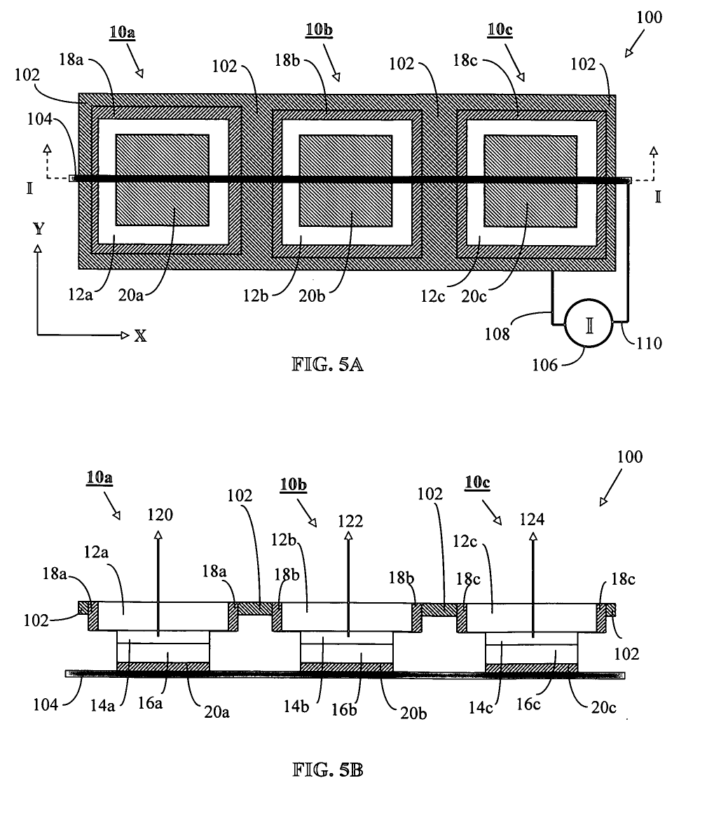

FIG. 5A illustrates a bottom plan view of another embodiment of this invention that includes a plurality of LEDs. FIG. 5B illustrates a cross-sectional view of this embodiment along the I-I indicated in FIG. 5A. In this example, the plurality of LEDs is a linear array 100 of three LEDs. The LEDs are labeled 10a, 10b and 10c. The linear array 100 of three LEDs is an example for illustrative purposes. The linear array may contain two LEDs, three LEDs or more than three LEDs. LEDs 10a, 10b and 10c in FIGS. 5A and 5B are structurally and functionally identical to LED 10 in FIGS. 1A and 1B. Each LED in FIGS. 5A and 5B has a first semiconductor layer (12a, 12b or 12c), an active region (14a, 14b or 14c), a second semiconductor layer (16a, 16b or 16c), a first electrode (18a, 18b or 18c) and a second electrode (20a, 20b or 20c).

The first electrodes (18a, 18b and 18c) of LEDs 10a, 10b and 10c in the linear array 100 are electrically connected via electrode 102. Electrode 102 is fabricated from the same material as the first electrodes 18a, 18b and 18c as well as electrode 18 in FIGS. 1A and 1B.

The second electrodes (20a, 20b and 20c) of LEDs 10a, 10b and 10c in the linear array 100 are electrically connected via electrode 104. Electrode 104 is fabricated from any electrically conducting metal. The connections may be made, for example, by wire bonding. Suitable metals were previously listed for electrodes 18 and 20 of LED 10 in FIGS. 1A and 1B.

A current source 106 is attached to the linear array 100 via electrically conducting wires 108 and 110. When the proper current is applied to the linear array 100 by current source 106, all three LEDs (10a, 10b and 10c) will emit light. Illustrative light rays 120, 122 and 124 indicate light emission from LEDs 10a, 10b and 10c, respectively.

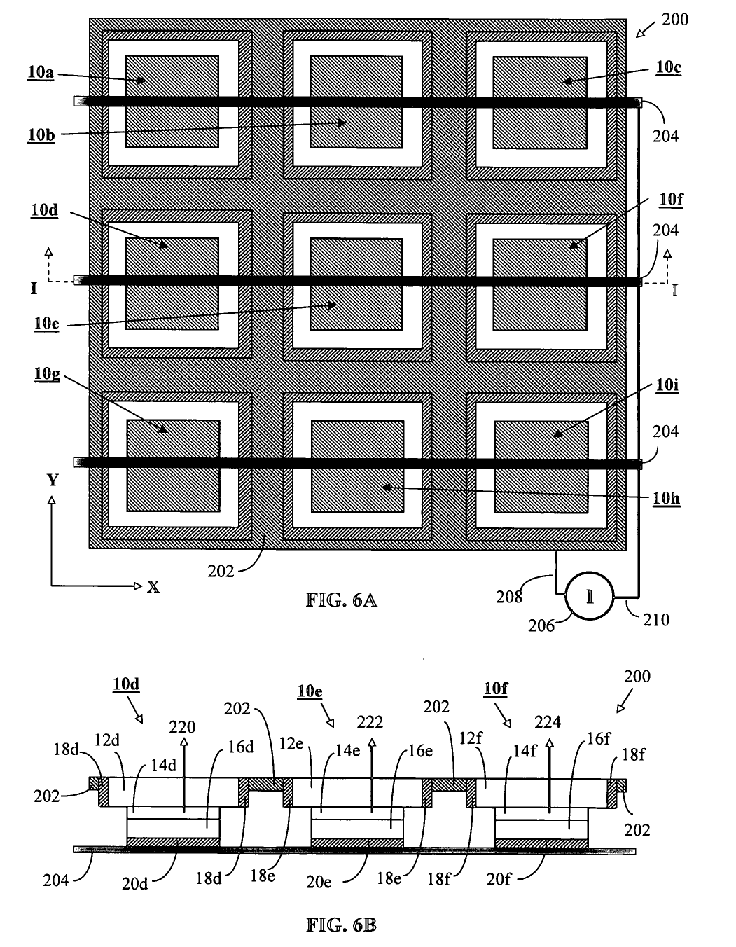

FIG. 6A illustrates a bottom plan view of another embodiment of this invention that includes a plurality of LEDs. FIG. 6B illustrates a cross-sectional view of this embodiment along the I-I indicated in FIG. 6A. In this example, the plurality of LEDs is a two-dimensional array 200 of nine LEDs. The LEDs are labeled 10a, 10b, 10c, 10d, 10e, 10f, 10g, 10h and 10i. The three LEDs shown in the cross-sectional view in FIG. 6B are 10d, 10e and 10f. The two-dimension array 200 of nine LEDs is an example for illustrative purposes. The two-dimensional array may contain four LEDs or more than four LEDs. The two-dimensional array may be a square-shaped array, a rectangular-shaped array or any other shape that contains at least two LEDs in each dimension. LEDs 10a, 10b, 10c, 10d, 10e, 10f, 10g, 10h and 10i n FIGS. 6A and 6B are structurally and functionally identical to LED 10 in FIGS. 1A and 1B. Each LED in FIGS. 6A and 6B has a first semiconductor layer (12a, 12b, 12c, 12d, 12e, 12f, 12g, 12h or 12i), an active region (14a, 14b, 14c, 14d, 14e, 14f, 14g, 14h or 14i), a second semiconductor layer (16a, 16b, 16c, 16d, 16e, 16f, 16g, 16h or 16i), a first electrode (18a, 18b, 18c, 18d, 18e, 18f, 18g, 18h or 18i) and a second electrode (20a, 20b, 20c, 20d, 20e, 20f, 20g, 20h or 20i).

The first electrodes (18a, 18b, 18c, 180d, 18e, 18f, 18g, 18h and 18i) of LEDs 10a, 10b, 10c, 10d, 10e, 10f, 10g, 10h and 1oi in the two-dimensional array 200 are electrically connected via electrodes 202. Electrode 202 is fabricated from the same material as the first electrodes 18a, 18b, 18c, 180d, 18e, 18f, 18g, 18h and 18i as well as electrode 18 in FIGS. 1A and 1B.

The second electrodes (20a, 20b, 20c, 20d, 20e, 20f, 20g, 20h and 20i) of LEDs 10a, 10b, 10c, 10d, 10e, 10f, 10g, 10h and 10i in the two-dimensional array 200 are electrically connected via electrodes 204 and conducting wire 210. Electrodes 204 are fabricated from any electrically conducting metal. The connections may be made, for example, by wire bonding. Suitable metals were previously listed for electrodes 18 and 20 of LED 10 in FIGS. 1A and 1B.

A current source 206 is attached to the two-dimensional array 200 via electrically conducting wires 208 and 210. When the proper current is applied to the two-dimensional array 200 by current source 206, all nine LEDs (10a, 10b, 10c, 10d, 10e, 10f, 10g, 10h and 10i) will emit light. Illustrative light rays 220, 222 and 224 indicate light emission from LEDs 10d, 10e and 10f, respectively in FIG. 6B.

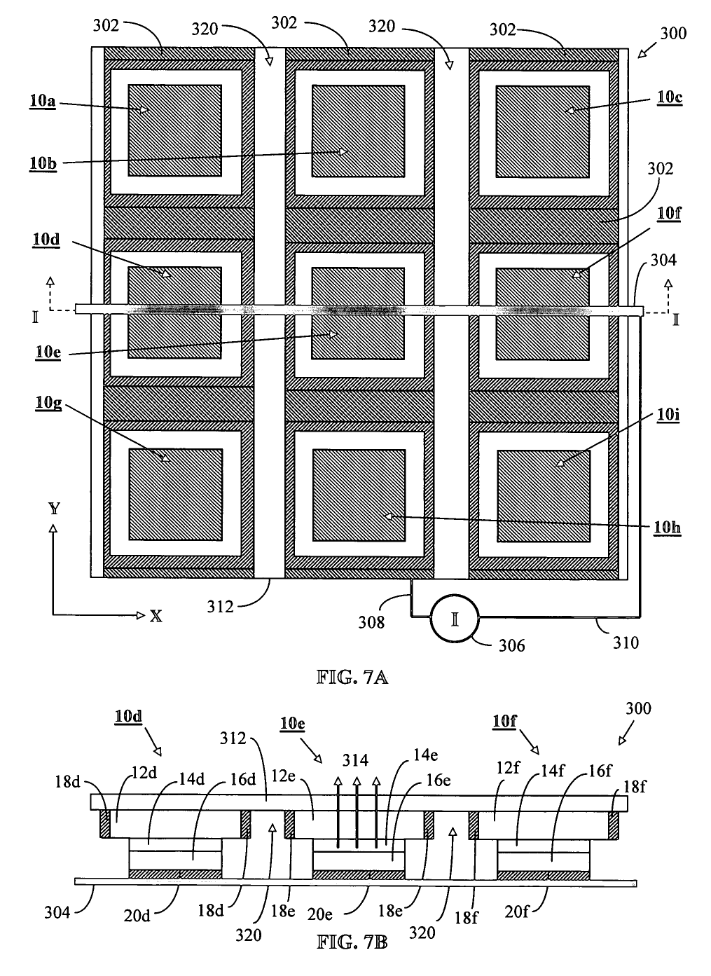

FIG. 7A illustrates a bottom plan view of another embodiment of this invention that includes a plurality of LEDs. FIG. 7B illustrates a cross-sectional view of this embodiment along the I-I indicated in FIG. 7A. In this example, the plurality of LEDs is a two-dimensional array 300 of nine LEDs. The LEDs are labeled 10a, 10b, 10c, 10d, 10e, 10f, 10g, 10h and 10i. The three LEDs shown in the cross-sectional view in FIG. 7B are 10d, 10e and 10f. The two-dimension array 300 of nine LEDs is an example for illustrative purposes. The two-dimensional array may contain four LEDs or more than four LEDs. The two-dimensional array may be a square-shaped array, a rectangular-shaped array or any other shape that contains at least two LEDs in each dimension. LEDs 10a, 10b, 10c, 10d, 10e, 10f, 10g, 10h and 10i in FIGS. 7A and 7B are structurally and functionally identical to LED 10 in FIGS. 1A and 1B. Each LED in FIGS. 7A and 7B has a first semiconductor layer (12a, 12b, 12c, 12d, 12e, 12f, 12g, 12h or 12i), an active region (14a, 14b, 14c, 14d, 14e, 14f, 14g, 14h or 14i),a second semiconductor layer (16a, 16b, 16c, 16d, 16e, 16f, 16g, 16h or 16i), a first electrode (18a, 18b, 18c, 18d, 18e, 18f, 18g, 18h or 18i) and a second electrode (20a, 20b, 20c, 20d, 20e, 20f, 20g, 20h or 20i).

The first electrodes of the LEDs in the two-dimensional array 300 are connected in columns by electrodes 302. The portions of electrodes 302 in the areas 320 between the columns have been removed to electrically isolate the columns. Since the electrode material has been removed in areas 320, a substrate 312 must be present to provide structural support for the two-dimensional array 300. The substrate 312 may be the original growth substrate used to fabricate the semiconductor layers of the LEDs. The first electrodes 18a, 18d and 18g are connected together in a first column; the first electrodes 18b, 18e and 18h are connected together in second column; and the first electrodes 18c, 18f and 18i are connected together in a third column. Electrodes 302 are fabricated from the same material as the first electrodes 18a, 18b, 18c, 180d, 18e, 18f, 18g, 18h and 18i as well as electrode 18 in FIGS. 1A and 1B.

The second electrodes of the LEDs in the two-dimensional array 300 are connected in rows by electrodes 304. For simplicity, only one electrode 304 is shown in the figures. For example, electrodes 20d, 20e and 20f are connected in a row by electrode 304 in FIG. 7A. Electrodes 20a, 20b and 20c and electrodes 20g, 20h and 20i are similarly connected in rows by electrodes 304 (but not shown in FIG. 7A). Electrodes 304 are fabricated from any electrically conducting metal. The connections may be made, for example, by wire bonding. Suitable metals were previously listed for electrodes 18 and 20 of LED 10 in FIGS. 1A and 1B.

A current source 306 is attached to the two-dimensional array 300 via electrically conducting wires 308 and 310. When the proper current is applied to the two-dimensional array 300 by current source 206, a single LED (10e) will emit light 314. By properly choosing electrodes of the appropriate row and column of the two-dimensional array 300, any LED in the array may be individually powered to emit light. By time and spatial sequencing of the light emission from the individual LEDs in the array, the array can be used in imaging applications such as two-dimensional displays. Each LED in the array is a pixel (picture element) of the display.

Another embodiment of this invention is a method for fabricating at least one light emitting diode. The process includes several steps.

The first step of the method for fabricating at least one light emitting diode is to provide a growth substrate onto which subsequent semiconductor layers are deposited. FIG. 8 illustrates a cross-sectional view of assembly 400 that consist of growth substrate 402. The growth substrate 402 has a crystal structure that allows for epitaxial growth of the semiconductor layers. The grow substrate is also optically transparent to the light required in any subsequent laser-assisted processing steps. Example growth substrates for GaN-based LED devices are sapphire (Al₂O₃) and silicon carbide (SiC). The preferred substrate for GaN-based LEDs is sapphire.

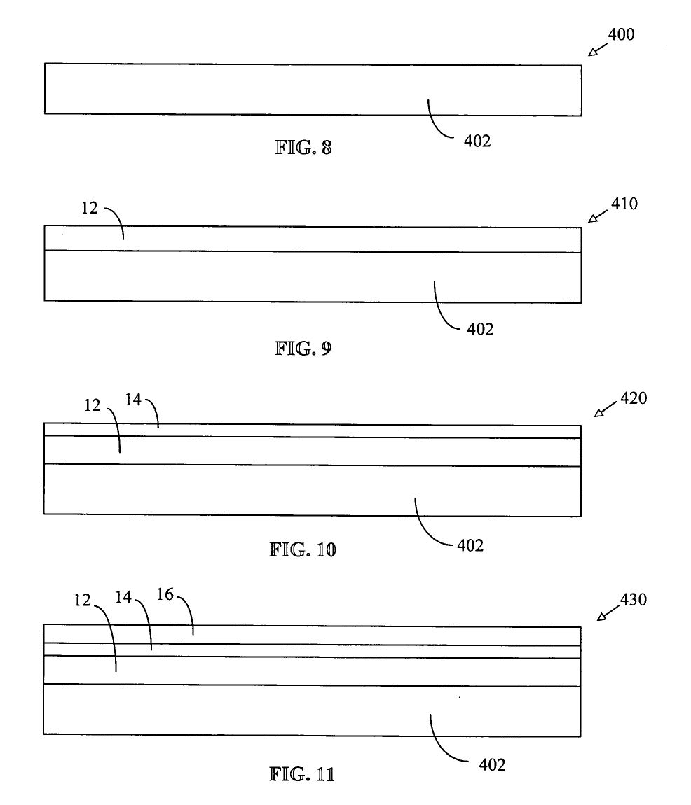

Another step of the method for fabricating at least one light emitting diode is to deposit a first doped semiconductor layer 12 onto the growth substrate 402. FIG. 9 illustrates a cross-section view of assembly 410, which includes the growth substrate 402 and the first doped semiconductor layer 12. Example semiconductor materials for the first doped semiconductor layer 12 have been listed previously. The first doped semiconductor layer 12 is also a current spreading layer. In order to increase the current spreading capability of the first doped semiconductor layer 12, preferably the first doped semiconductor layer is greater than 2 microns thick. More preferably, the thickness of the first doped semiconductor layer is greater than 5 microns thick. Most preferably, the thickness of the first doped semiconductor layer is greater than 10 microns thick. If the LED is a GaN-based device, preferably the first doped semiconductor layer 12 is an n-doped GaN layer.

Semiconductor layers such as the first doped semiconductor layer 12 can be deposited onto a growth substrate using a variety of deposition methods. Deposition methods can include, for example, chemical vapor deposition (CVD), metal-organic chemical vapor deposition (MOCVD), molecular beam epitaxy MBE), liquid phase epitaxy (LPE), vapor phase epitaxy (VPE), and hydride vapor phase epitaxy (HVPE), but are not limited to these methods. When a layer of semiconductor material is deposited onto a growth substrate, tensile or compressive stresses can occur that affect the planarity of the deposited film as well as the electrical and optical properties of the semiconductor layer. For example, HVPE exhibits very high deposition rates and reasonable crystal quality for GaN growth on growth substrates such as sapphire. Attempts to grow GaN layers thicker than 20 microns, however, can result in cracking, especially for doped layers. For GaN-based LEDs, preferably the first doped semiconductor layer 12 is an n-doped GaN layer that is grown by HVPE.

Another step of the method for fabricating at least one light emitting diode is to deposit an active region 14 onto the first doped semiconductor layer 12. FIG. 10 illustrates a cross-section view of assembly 420, which includes the growth substrate 402, the first doped semiconductor layer 12 and the active region 14. The active region is deposited using one of the deposition methods listed above.

Another step of the method for fabricating at least one light emitting diode is to deposit a second doped semiconductor layer 16 onto the active region 14. FIG. 11 illustrates a cross-section view of assembly 430, which includes the growth substrate 402, the first doped semiconductor layer 12, the active region 14 and the second doped semiconductor layer 16. The second doped semiconductor layer 16 is deposited using one of the deposition methods listed above.

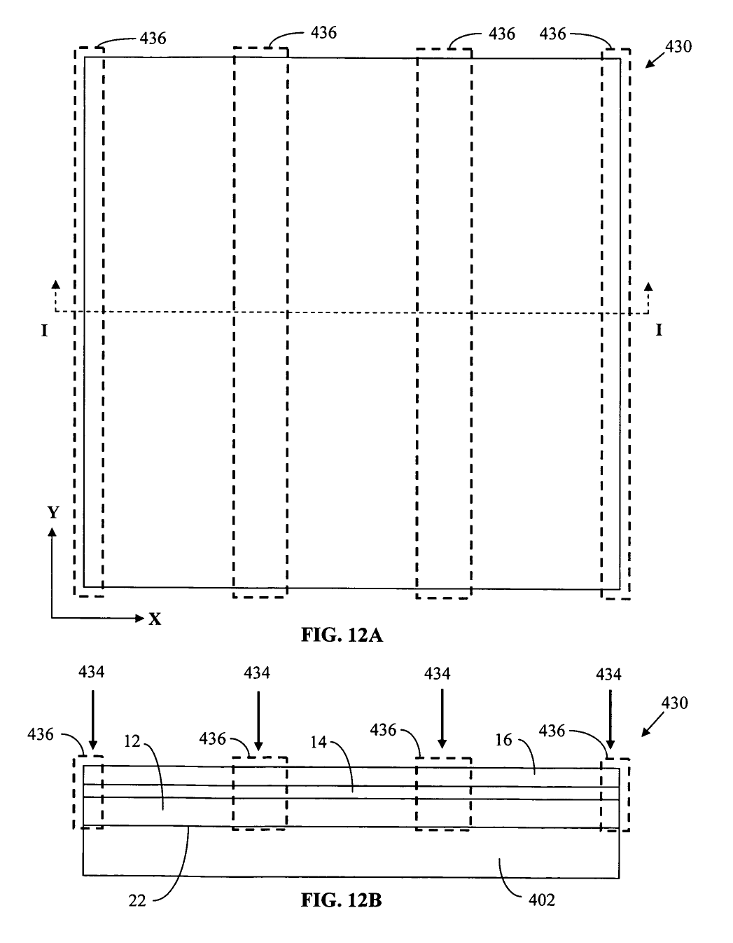

Assembly 430 is illustrated again in FIG. 12A and FIG. 12B. FIG. 12A is a top plan view of assembly 430 and FIG. 12B is a cross-sectional view of assembly 430 along the I-I plane shown in FIG. 12A.

Another step of the method for fabricating at least one light emitting diode is to etch a first array of parallel trenches through the second semiconductor layer 16, the active region 14 and the first semiconductor layer 12. The areas that are removed by the etching process are enclosed inside the dashed lines 436 in FIGS. 12A and 12B.

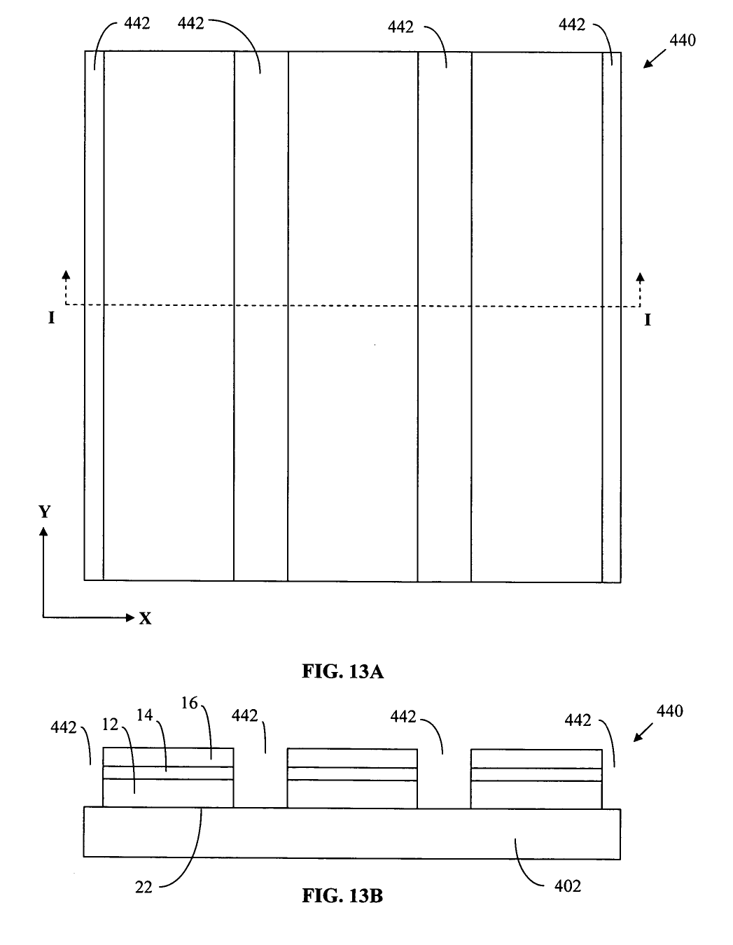

The resulting first array of parallel trenches 442 is illustrated in assembly 440 in FIGS. 13A and 13B. FIG. 13A is a top plan view of assembly 440. FIG. 13B is a cross-sectional view along the I-I plane shown in FIG. 13A. The first array of parallel trenches 442 is parallel to the y-axis. The etching process is stopped at the first surface 22 of the first doped semiconductor layer 12. The trenches 442 are shown with vertical sidewalls. However, trenches 442 may also have angled sidewalls if desired. In FIGS. 13A and 13B, the first array of trenches divides the semiconductor layers into three columns of semiconductor material. Three columns were chosen for illustrative purposes only. The number of columns may also be less than three or more than three.

The etching process can be a dry etching process or a wet etching process. Dry etching processes include reactive ion etching, plasma etching and laser etching. The preferred etching process is a laser etching process using laser light 434. Laser etching generally has a higher etch rate than other etching processes. Laser etching is done by laser ablation using a pulsed laser. Example lasers for laser etching include, but are not limited to, diode-pumped solid-state lasers and excimer lasers. Examples of diode-pumped solid-state lasers are frequency-tripled or frequency-quadrupled yttrium-aluminum-garnet (YAG) lasers operating at 355 nm or at 266 nm, respectively. Examples of excimer lasers are argon-fluoride excimer lasers that emit light at 193 nm or krypton fluoride excimer lasers that emit light at 248 nm.

In order to prevent leakage currents along the sides of the trenches after the laser etching process, it may be necessary to utilize a subsequent second etching process to clean the surface. The second etching process may be, for example, reactive ion etching, plasma etching or another laser etching process.

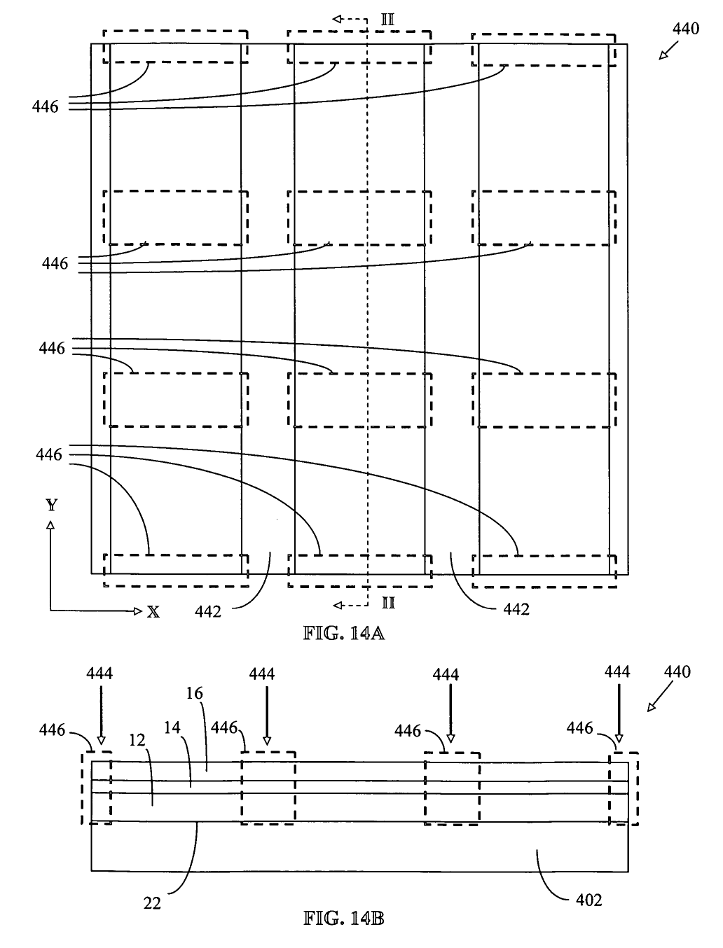

Assembly 440 is illustrated again in FIG. 14A and FIG. 14B. FIG. 14A is a plan view of assembly 440 and FIG. 14B is a cross-sectional view of assembly 440 along the II-II plane shown in FIG. 14A.

Another step of the method for fabricating at least one light emitting diode is to etch a second array of parallel trenches through the second semiconductor layer 16, the active region 14 and the first semiconductor layer 12. The areas that are removed by the etching process are enclosed inside the dashed lines 446 in FIGS. 14A and 14B.

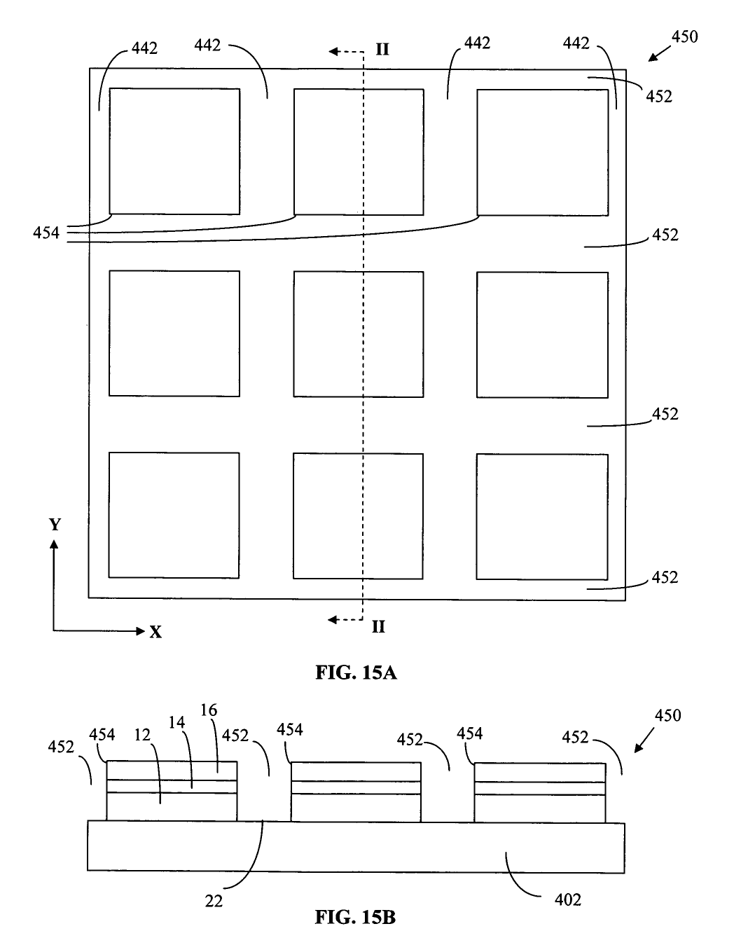

The resulting second array of parallel trenches 452 is illustrated in assembly 450 in FIGS. 15A and 15B. FIG. 15A is a top plan view of assembly 450. FIG. 15B is a cross-sectional view along the II-II plane shown in FIG. 15A. The second array of parallel trenches 452 is parallel to the x-axis and substantially perpendicular to the first array of parallel trenches 442. The first array of parallel trenches 442 and the second array of parallel trenches 452 form isolated dies 454 attached to the growth substrate 402. The etching process for the second array of parallel trenches is stopped at the first surface 22 of the first doped semiconductor layer 12. Example etching processes are listed above. The preferred etching process is a laser etching process using laser light 444. Laser etching is done by laser ablation using a pulsed laser. Trenches 452 are illustrated with vertical sidewalls. However, trenches 452 may also have angled sidewalls if desired. In FIGS. 15A and 15B, the second array of trenches divides the semiconductor layers into three rows of semiconductor dies. Three rows were chosen for illustrative purposes only. The number of rows may also be less than three or more than three.

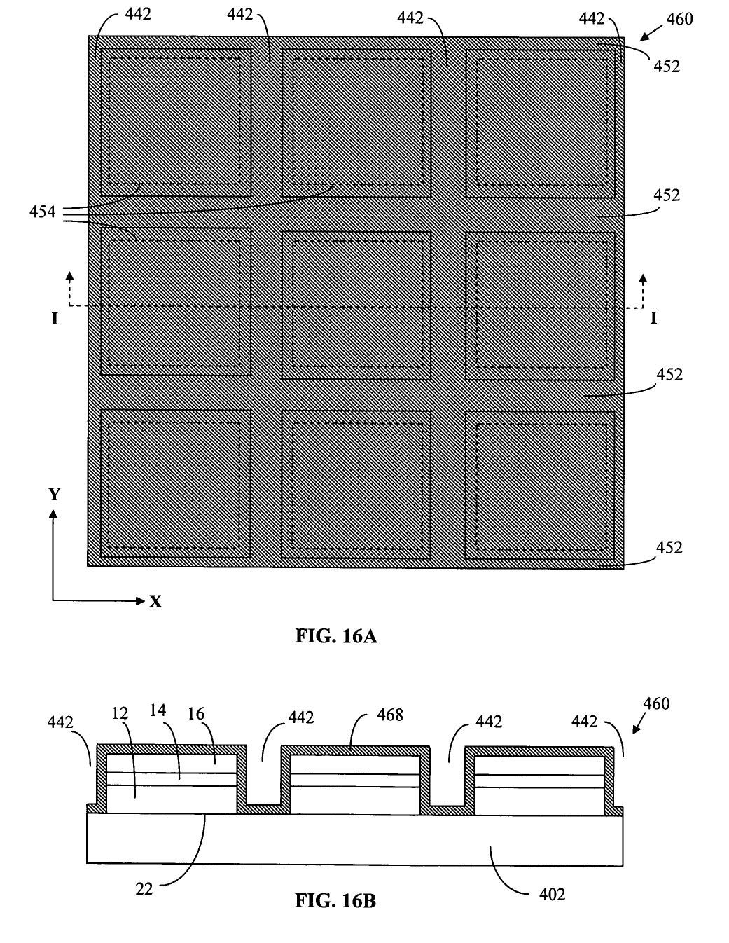

Another step in the method for fabricating at least one light emitting diode is to deposit a metal layer 468 over the exposed surfaces of the second doped semiconductor layer 16, the exposed surfaces of the first array of parallel trenches 442 and the exposed surfaces of the second array of parallel trenches 452. The exposed surfaces of the first array of parallel trenches 442 and the exposed surfaces of the second array of parallel trenches 452 include the edges of the second doped semiconductor layer 16, the edges of the active region, the edges of the first doped semiconductor layer and the exposed surfaces of the grow substrate 402. The resulting assembly 460 is shown in FIGS. 16A and 16B. FIG. 16A is a top plan view of assembly 460 and FIG. 16B is a cross-sectional view along the I-I plan shown in FIG. 16A. Appropriate materials for the metal layer may include one or more electrically conducting metals or metal alloys containing, but not limited to, silver, aluminum, nickel, gold, titanium, chromium, platinum, palladium, rhodium, rhenium, ruthenium and tungsten.

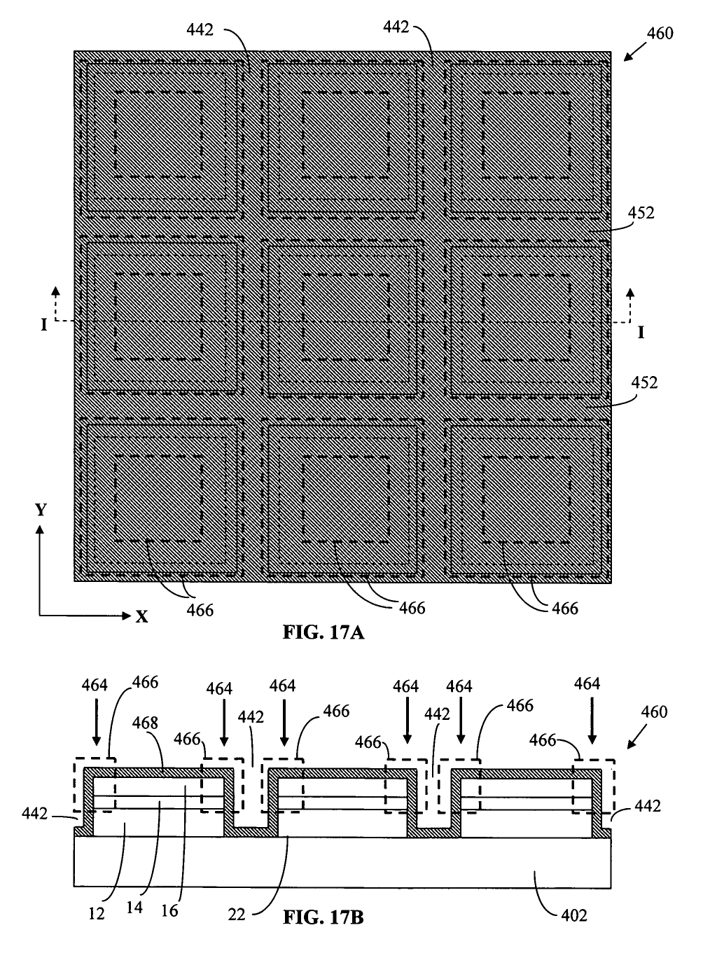

Assembly 460 is illustrated again in FIGS. 17A and 17B. FIG. 17A is a top plan view of assembly 460. FIG. 17B is a cross-sectional view along the I-I plane shown in FIG. 17A.

Another step in the method for fabricating at least one light emitting diode is to remove, via a laser etching process directed along the edges of the isolated dies, the metal layer 468 covering the second doped semiconductor layer, the second doped semiconductor layer, the metal layer covering the edges of the active region and the active region. The areas that are removed by the laser etching process are enclosed inside the dashed lines 466 in FIGS. 17B. The areas that are removed in FIG. 17A are the areas between concentric pairs of dashed lines 466.

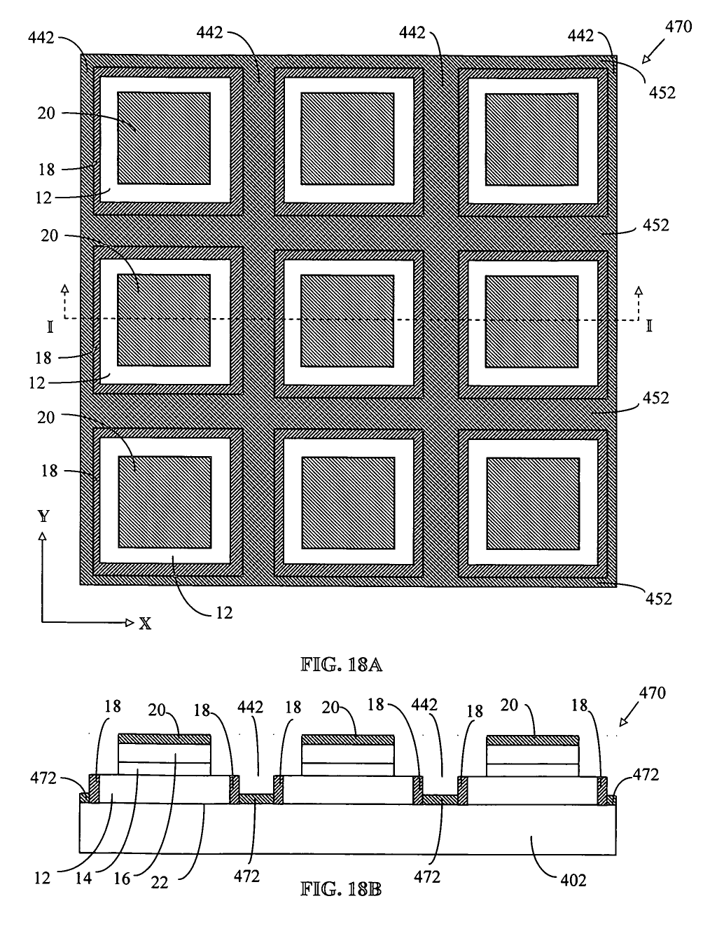

The resulting etched structure is illustrated as assembly 470 in FIGS. 18A and 18B. FIG. 18A is a top plan view of assembly 470. FIG. 18B is a cross-sectional view along the I-I plan shown in FIG. 18A. The metal layers on the edges of the first semiconductor layers of the isolated dies form first electrodes 18. The metal layers on the second semiconductor layers of the isolated dies form second electrodes 20. The first electrodes 18 of the isolated dies are electrically connected via remaining portions 472 of the metal layer. The second electrodes 20 of the isolated dies are electrically isolated.

Assembly 470 as illustrated in FIGS. 18A and 18B now consists of a two-dimensional array of isolated LED dies that have first electrodes 18 and second electrodes 20. The first electrodes 18 of all the dies are electrically connected. The dies are all still attached to the growth substrate 402. At this point, there are several options available. In the first option, the dies can be removed from the growth substrate as a single two-dimensional array of LED dies having the first electrodes of all the dies electrically connected. As a second option, the two-dimensional array of dies can be divided into linear (one-dimensional) arrays of dies. The dies can be separated into columns of linear arrays of dies. The columns of linear arrays of dies can be left attached to the growth substrate or the columns of linear arrays of dies can be removed from the growth substrate. As a third option, the two-dimensional array of dies can be divided into single dies. The single dies can be removed from the growth substrate if desired. These options will be described in more detail below.

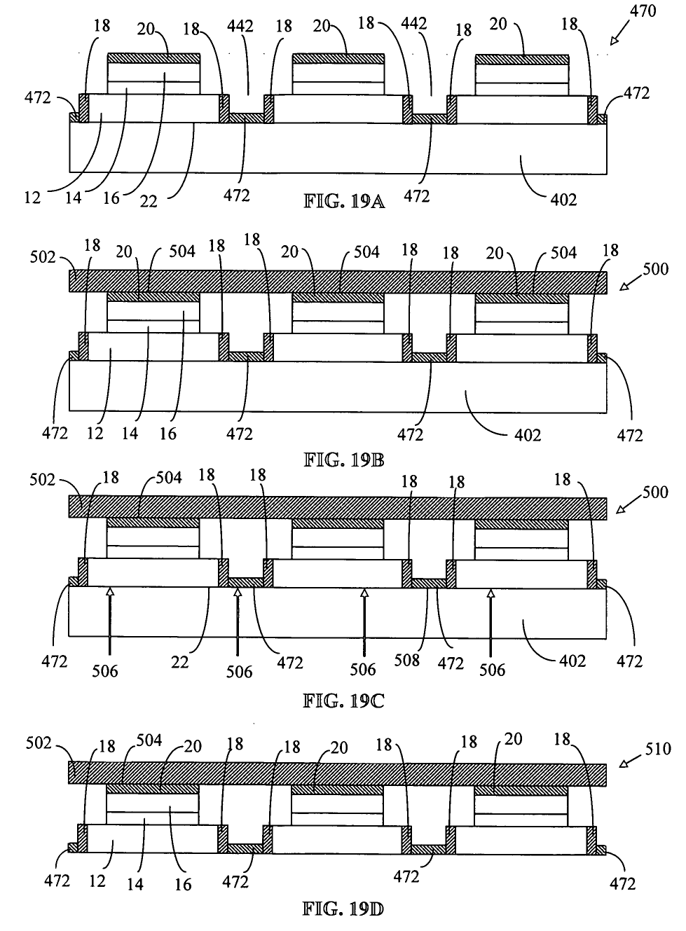

Starting with assembly 470, shown again in cross-section in FIG. 19A, another embodiment of this invention is a method for fabricating at least one light emitting diode. The first step of the method for fabricating at least one light emitting diode is to attach a transfer substrate 502 to the surfaces 504 of the second electrodes 20 as shown for assembly 500 in FIG. 19B. Attachment of the transfer substrate 502 may be accomplished by any means, including, but not limited to, a eutectic solder, an adhesive, or waxes. The transfer substrate may be an electrical conductor, an insulator or a semiconductor. If the transfer substrate is attached permanently to the second electrodes 20, preferably the transfer substrate 502 is an electrical conductor and the attachment is done with a eutectic solder.

Another step in the method for fabricating at least one light emitting diode is to remove the growth substrate 402 from assembly 500. Removal of the growth substrate 402 maybe accomplished via a laser liftoff process, chemical etching, or mechanical means. Preferably a laser liftoff process is used to remove the growth substrate. Lasers for the laser liftoff process include, but are not limited to, excimer lasers. Exemplary excimer lasers are argon-fluoride excimer lasers that emit light at 193 nm or krypton fluoride excimer lasers that emit light at 248 nm.

FIG. 19C illustrates laser light 506 passing through the transparent growth substrate 402 of assembly 500. The laser light 506 is incident at the first surfaces 22 of the first doped semiconductor layer 12 and surfaces 508 of the first electrodes 18 and metal layer 472. The laser light 506 causes the growth substrate 402 to detach from the first semiconductor layers 12, the first electrodes 18 and the metal layer 472.

When the growth substrate is removed from assembly 500, the resulting structure is assembly 510. Assembly 510 is illustrated in cross-section in FIG. 19D. Assembly 510 is a two-dimensional array of LED dies, where the first electrodes 18 of the dies are electrically connected.

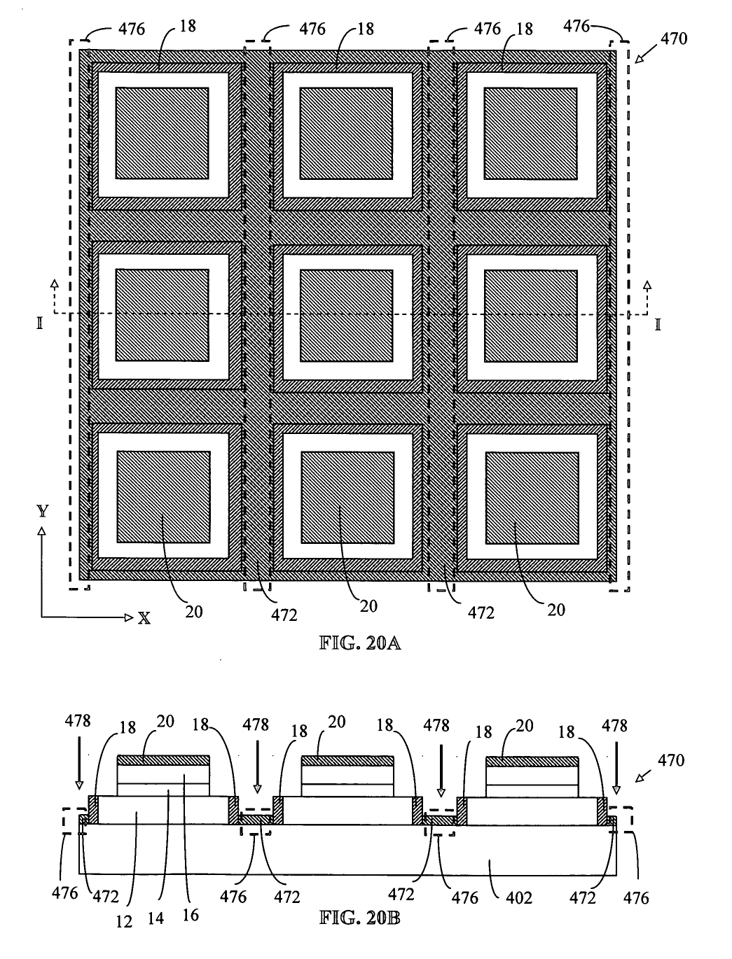

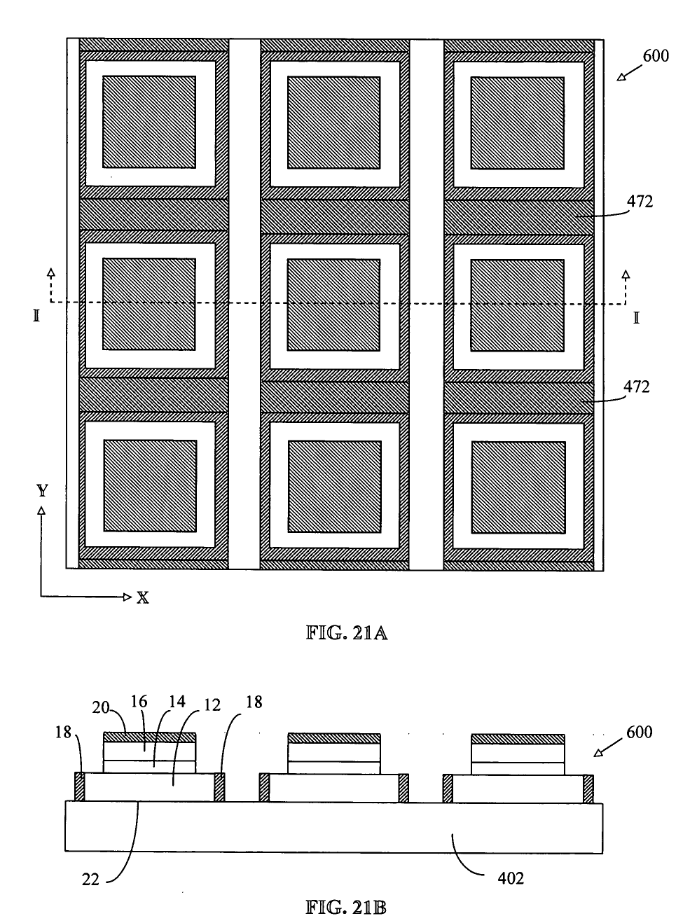

Starting with assembly 470, shown again in a top plan view in FIG. 20A and in cross-section in FIG. 20B, another embodiment of this invention is a method for fabricating at least one light emitting diode. The first step of the method for fabricating at least one light emitting diode is to remove, via an etching process, portions of the metal layer 472 located at the bottom of the first array of parallel trenches 442 of assembly 470 (the trenches 442 are illustrated on assembly 460 in FIGS. 16A and 16B). Preferably the etching process is a laser etching process. The sections of the metal layer 472 that will be removed are outlined by dashed lines 476. Laser light 478 is directed at the areas outlined by the dashed lines 476. After the metal areas inside the dashed lines are removed, the result is assembly 600 illustrated in FIGS. 21 A and 21B. FIG. 21A is a top plan view of assembly 600 and FIG. 21B is a cross-sectional view along the I-I plane indicated in FIG. 21A. Assembly 600 consists of three linear arrays of LED dies where each linear array contains three LED dies. The first electrodes 18 of the three dies in each linear array are electrically connected by metal layer 472.

If desired, the linear arrays of dies may be attached to a transfer substrate and the linear arrays subsequently removed from the growth substrate by a liftoff process (not shown). The attachment of the transfer substrate and the liftoff process were described previously.

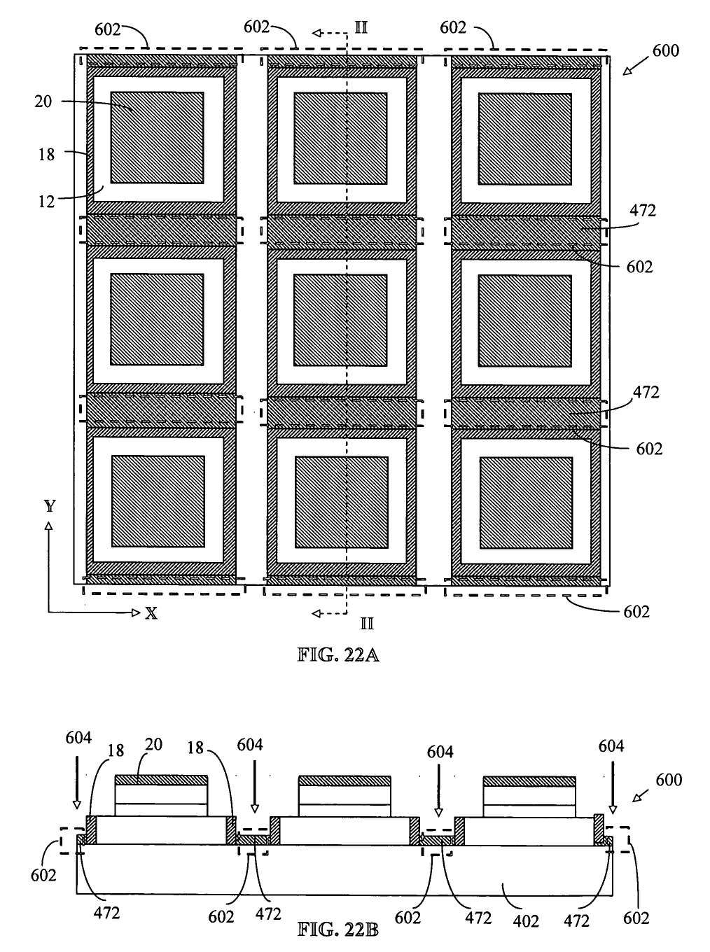

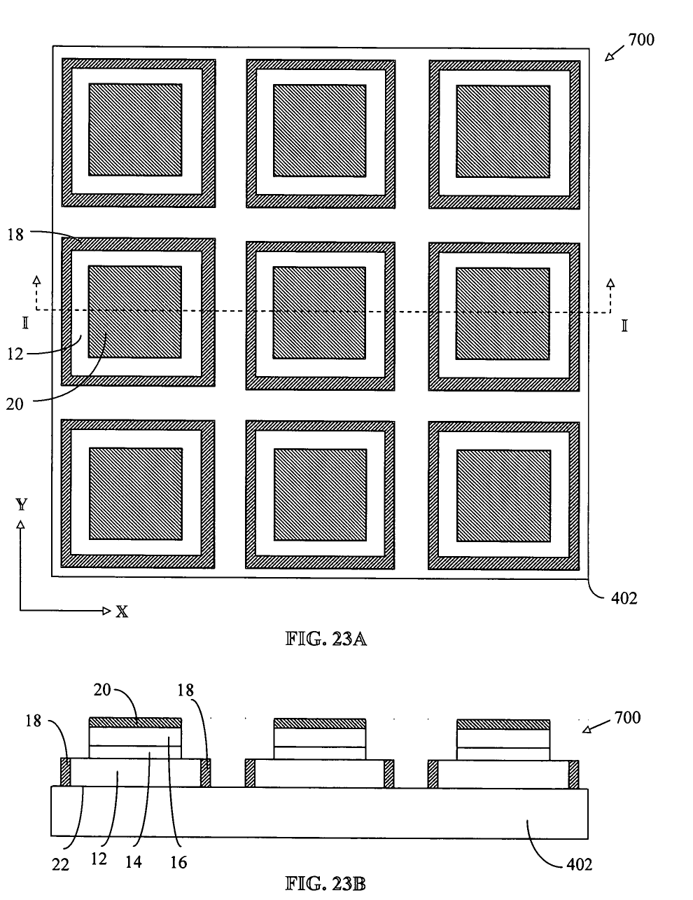

Starting with assembly 600, shown again in a top plan view in FIG. 22A and in cross-section in FIG. 22B, another embodiment of this invention is a method for fabricating at least one light emitting diode. The first step of the method for fabricating at least one light emitting diode is to remove, via an etching process, portions of the metal layer 472 located at the bottom of the second array of parallel trenches 452 of assembly 600 (the trenches 452 are illustrated on assembly 460 in FIGS. 16A and 16B). Preferably the etching process is a laser etching process. The sections of the metal layer 472 that will be removed are outlined by dashed lines 602. Laser light 604 is directed at the areas outlined by the dashed lines 602. After the metal areas inside the dashed lines are removed, the result is assembly 700 illustrated in FIGS. 23A and 23B. FIG. 23A is a top plan view of assembly 700 and FIG. 23B is a cross-sectional view along the I-I plane indicated in FIG. 23A. Assembly 700 consists of nine LED dies that are still attached to the growth substrate 402. The LED dies in assembly 700 are similar to the light emitting diode 10 of FIG. 1 except mounted on the growth substrate 402.

If desired, the nine dies may be attached to a transfer substrate and the dies subsequently removed from the growth substrate by a liftoff process (not shown). The attachment of the transfer substrate and the liftoff process were described previously. The transfer substrate may then be diced into nine pieces (not shown), forming nine single LEDs.

While the invention has been described in conjunction with specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

What is claimed is:

1. At least one light emitting diode, comprising:
a first doped semiconductor layer, wherein said first doped semiconductor layer has a first surface, a second surface opposite and substantially parallel to said first surface and an edge surface that connects said first surface and said second surface, wherein said first doped semiconductor layer has a first sectional area in a plane substantially parallel to said second surface, and wherein said first doped semiconductor layer is a current spreading layer;
an active region underlying and in contact with said second surface of said first semiconductor doped layer, wherein said active region emits light, wherein said active region has a second sectional area in a plane substantially parallel to said second surface, and wherein said second sectional area is less than said first sectional area of said first doped semiconductor layer;
a second doped semiconductor layer underlying and in contact with said active region;
a first electrode, wherein said first electrode is in contact with said edge surface of said first doped semiconductor layer; and
a second electrode underlying and in contact with said second doped semiconductor layer.

2. At least one light emitting diode as in claim 1, wherein said first doped semiconductor layer is an n-doped semiconductor layer and said second doped semiconductor layer is a p-doped semiconductor layer.

3. At least one light emitting diode as in claim 2, wherein said n-doped semiconductor layer and said p-doped semiconductor layer are gallium nitride layers.

4. At least one light emitting diode as in claim 3, wherein said n-doped semiconductor layer is greater than 2 microns thick.

5. At least one light emitting diode as in claim 4, wherein said n-doped semiconductor layer is greater than 5 microns thick.

6. At least one light emitting diode as in claim 5, wherein said n-doped semiconductor layer is greater than 10 microns thick.

7. At least one light emitting diode as in claim 4, wherein said n-doped semiconductor layer is formed by hydride vapor phase epitaxy.

8. At least one light emitting diode as in claim 5, wherein said active region is a p-n homojunction, a p-n heterojunction, a p-n double heterojunction, a single quantum well, or a multiple quantum well.

9. At least one light emitting diode as in claim 5, wherein said first electrode covers substantially all of said edge surface of said first doped semiconductor layer.

10. At least one light emitting diode as in claim 1, wherein said second electrode is silver.

11. At least one light emitting diode as in claim 1, wherein said at least one light emitting diode is a plurality of light emitting diodes.

12. At least one light emitting diode as in claim 11, wherein said plurality of light emitting diodes is a linear array of light emitting diodes.

13. At least one light emitting diode as in claim 12, wherein said first electrodes of said light emitting diodes in said linear array of said light emitting diodes are electrically connected.

14. At least one light emitting diode as in claim 11, wherein said plurality of said light emitting diodes is a two-dimensional array of said light emitting diodes and wherein said two-dimensional array is divided into rows of said light emitting diodes and columns of said light emitting diodes and wherein said rows of said light emitting diodes are substantially perpendicular to said columns of said light emitting diodes.

15. At least one light emitting diode as in claim 14, wherein said first electrodes of said light emitting diodes in said two-dimensional array are electrically connected.

16. At least one light emitting diode as in claim 14, wherein said first electrodes of said light emitting diodes in each of said columns of said two-dimensional array are electrically connected.

17. At least one light emitting diode as in claim 16, wherein said second electrodes of said light emitting diodes in each of said rows of said two-dimensional array are electrically connected.

18. At least one light emitting diode as in claim 17, wherein when a current is applied to said first electrode of a first column of said two-dimensional array and to said second electrode of a first row of said two-dimensional array, said light emitting diode located at an intersection of said first row and said first column emits light.

19. At least one light emitting diode as in claim 1, further comprising an array of light extracting elements positioned on said first surface of said first doped semiconductor layer.

20. At least one light emitting diode as in claim 1, further comprising at least one reflector, whereby said at least one reflector is positioned adjacent to said second surface of said first doped semiconductor layer and whereby said at least one reflector is also positioned adjacent to said edge surfaces of said active region and said second doped semiconductor layer.

21. At least one light emitting diode as in claim 1, further comprising a wavelength conversion layer, whereby said wavelength conversion layer converts light of a first wavelength range emitted by said active region into light of a second wavelength range and whereby said second wavelength range is different than said first wavelength range.

22. A method for fabricating at least one light emitting diode, comprising the steps of:
providing a growth substrate;
depositing a first doped semiconductor layer onto one surface of said growth substrate;
depositing an active region on said first doped semiconductor layer;
depositing a second doped semiconductor layer on said active region;
etching a first array of parallel trenches through said second doped semiconductor layer, through said active region and through said first doped semiconductor layer;
etching a second array of parallel trenches through said second doped semiconductor layer, through said active region and through said first doped semiconductor layer, wherein said second array of parallel trenches is substantially perpendicular to said first array of parallel trenches and wherein said first array of parallel trenches and said second array of parallel trenches form isolated dies attached to said growth substrate;
depositing a metal layer over said exposed surfaces of said second doped semiconductor layer, said exposed surfaces of said first array of parallel trenches and said exposed surfaces of said second array of parallel trenches, wherein said exposed surfaces of said first array of parallel trenches and said exposed surfaces of said second array of parallel trenches include edges of said second doped semiconductor layer, edges of said active region, edges of said first doped semiconductor layer and exposed surfaces of said growth substrate at the bottom of said trenches; and
removing, via a laser etching process directed along the edges of the isolated dies, said metal layer covering said second doped semiconductor layer and said second doped semiconductor layer, said metal layer covering said edges of said active region and said active region, whereby said metal layers on said edges of said first semiconductor layers of said isolated dies form first electrodes, whereby said metal layers on said second semiconductor layers of said isolated dies form second electrodes, whereby said first electrodes of said isolated dies are electrically connected and whereby said second electrodes of said isolated dies are electrically isolated.

23. A method for fabricating at least one light emitting diode as in claim 22, further comprising the steps of:
attaching a transfer substrate to said second electrodes covering said second doped semiconductor layers of said isolated dies;
removing, utilizing a liftoff process, said growth substrate from said isolated dies, thereby forming a two-dimensional array of isolated dies wherein said first electrodes of the isolated dies are electrically connected.

24. A method for fabricating at least one light emitting diode as in claim 22, further comprising the step of:
removing, via a laser etching process directed at the bottom of said first array of parallel trenches, said metal layer that is in contact with said growth substrate, whereby said isolated dies located between adjacent trenches of said first array of parallel trenches form at least one linear array of said isolated dies and whereby said first electrodes of said isolated dies in said at least one linear array of said isolated dies are electrically connected.

25. A method for fabricating at least one light emitting diode as in claim 24, further comprising the steps of:
attaching a transfer substrate to said second electrodes of said at least one linear array of said isolated dies; and
removing, via a liftoff process, said growth substrate from said at least one linear array of said isolated dies.

26. A method for fabricating at least one light emitting diode as in claim 24, further comprising the step of:
removing, via a laser etching process directed at the bottom of said second array of parallel trenches, said metal layer that is in contact with said growth substrate, thereby disconnecting said first electrodes of the isolated dies.

27. A method for fabricating at least one light emitting diode as in claim 26, further comprising the steps of:
attaching a transfer substrate to said second electrodes covering said second doped semiconductor layers of said isolated dies; and
removing, via a liftoff process, said growth substrate from said isolated dies.
